(19) United States
(12) Patent Application Publication
(10) Pub. No.: US 2019/0020359 A1
(43) Pub. Date: Jan. 17, 2019

(54) SYSTEMATIC CODING TECHNIQUE FOR ERASURE CORRECTION

(71) Applicant: Memoscale AS, Trondheim (NO)

(72) Inventors: Danilo Gligoroski, Trondheim (NO); Katina Kralevska, Trondheim (NO)

(21) Appl. No.: 16/065,478

(22) PCT Filed: Dec. 23, 2016
(86) PCT No.: PCT/EP2016/082656

§ 371 Date: Jun. 22, 2018

(30) Foreign Application Priority Data
Dec. 24, 2015 (GB) 1522869.5

(51) Int. Cl. H03M 13/37; H03M 13/13; H03M 13/03; G06F 11/10; G06F 17/16

(52) U.S. Cl. CPC H03M 13/373; H03M 13/13; G06F 17/16; H03M 13/3761; G06F 11/1076; H03M 13/036

(57) ABSTRACT

Disclosed herein is a method for determining how to encode data in accordance with a systematic coding technique and encoding data in accordance with the determined systematic coding technique. The method includes: determining code parameters; determining source data nodes that comprise source data that is not encoded by the systematic coding technique; for each of the redundant nodes, determining to generate each of the substripes of data in dependence on a combination of a different substripe from each of the source data nodes; and determining each of one or more of the substripes of at least one of the redundant nodes to be further dependent on at least one further substripe of source data that it is not currently dependent on.

### FIELD

The field of the invention is the systematic coding of data. A particularly preferred application for coded data according to embodiments is in a data storage system. The flexible code construction allows the coding to be adapted to the underlying hardware of the storage system configuration. In addition, the amount of data that is accessed and transferred in order to reconstruct unavailable data is significantly reduced from other coding techniques, such as Reed-Solomon coding.

### BACKGROUND

An ever increasing amount of data is being stored in large capacity distributed data storage systems. It is normal for redundancy to be introduced into stored data. The redundancy allows data within a node to be obtained when the node is unavailable, for example due to maintenance of the node or failure of part of the data storage system. The traditional approach to redundancy is replication of the stored data and one or more copies of the original data are stored in other node(s). Triple replication of stored data is an accepted industry standard. However, a problem with replication is that it has a high storage overhead. There is therefore an increasing use of erasure codes to store data as the property of being able to recover data is maintained and the storage overhead greatly reduced. Reed-Solomon (RS) codes, for example, are a widely employed erasure coding technique.

In addition to the extent to which unavailable data can be reconstructed, there are other desirable properties in a distributed data storage system, such as a small repair bandwidth and access-optimality. Repair bandwidth is the amount of transferred data required to repair a data storage unit in a data storage system in which the data is unavailable, referred to herein as a failed node. Access-optimality is achieved when the amount of accessed and transferred data during the repair process is equal. There are two types of repair of a failed node, functional and exact repair. Under functional repair, a failed node is replaced by a new node such that the resulting system continues to possess the data-reconstruction and repair properties. With exact repair, the new node has exactly the same content as the lost data. Exact repair is preferred over functional repair from a practical point of view.

In a (n, k, d) systematic erasure code for a data storage system, there are n nodes that store data. Of the n nodes, k of the nodes store source data that is data that has not been encoded by the erasure coding technique. There are r redundant nodes, where r=n−k. Each of the r redundant nodes stores data that has been coded according to the erasure coding technique. The file size, i.e. amount of source data that is stored, is B. The amount of data stored in each node is A_{N}, where A_{N}=B/k. The data from a failed node is recovered by transferring data from d non-failed nodes (i.e. nodes that are available). The repair bandwidth β is greater than or equal to the lower bound that is A_{N}.

A large number of erasure coding techniques exist with differing properties. The codes are designed to have one or more of the desired properties of being Maximum-Distance Separable (MDS), systematic, achieving optimal repair bandwidth, and offering access optimality.

An erasure coding technique is presented in the paper G. K. Agarwal, B. Sasidharan, and P. Vijay Kumar, ‘An alternate construction of an access-optimal regenerating code with optimal sub-packetisation level’, National Conference on Communications (NCC), pages 1-6, February 2015, referred to herein as the Agarwal paper. In the Agarwal paper, the data in each node is stored in α substripes (i.e. sub-packets). The reconstruction of unavailable data is performed by operations on substripes of data within available nodes. The sub-packetisation level represents the minimum dimension over which all operations are performed. When the sub-packetisation level is 1, as it is for standard RS codes, then each node is recovered by transferring data of size B/k from k nodes, i.e., the total amount of the transferred data is B. Thus, the repair bandwidth is equal to the file size when RS codes are used. By using a sub-packetisation level α>1, the repair bandwidth can be decreased from B. The Agarwal paper discloses the use of a sub-packetisation level of α=r^{m} where m=k/r. An essential condition to be able to construct the disclosed codes in the Agarwal paper is that m is an integer. The Agarwal paper does not disclose any technique for generating codes with any other sub-packetisation level than r^{m}. In addition, the Agarwal paper does not disclose any technique for generating a codes for which m is not an integer.

A different coding technique from that in the Agarwal paper is disclosed in the paper ‘A “Hitchhiker's” Guide to Fast and Efficient Data Reconstruction in Erasure-coded Data Centres’ by K. V. Rashimi et al, SIGCOMM 2014, Computer Communication Review, August 2014, referred to herein as the Hitchhiker paper. The Hitchhiker paper discloses a technique for improving on RS coding by using a sub-packetisation level of exactly 2 only.

There is a need to improve known erasure coding techniques.

### SUMMARY

According to a first aspect of the invention, there is provided a method for determining how to encode data in accordance with a systematic coding technique, the method comprising: determining the code parameters n, k, r and α, wherein n is the total number of nodes, k is the total number of source data nodes, r is the total number of redundant data nodes, such that n=k+r, α is the number of substripes of data in one of the nodes and each of the source data nodes and redundant data nodes comprise the same number of substripes, and wherein α is determined so that it satisfies the condition 1<α≤r^{m}, where m=ceiling(k/r); determining source data nodes that comprise source data that is not encoded by the systematic coding technique; for each of the redundant nodes, determining to generate each of the substripes of data in dependence on a combination of a different substripe from each of the source data nodes such that each of the substripes is generated in dependence on a combination of k substripes of source data and the α substripes of the redundant node are generated in dependence on all of the (α×k) substripes of source data; and determining each of one or more of the substripes of at least one of the redundant nodes to be further dependent on at least one further substripe of source data that it is not currently dependent on.

Preferably, (k/r) is not an integer.

Preferably, r is 2 or more, and/or r is 3 or more.

Preferably, α is 2 or more, and/or α is 3 or more.

Preferably, α is determined so that it satisfies the condition 1<α<r^{m} and/or (k/r) is not an integer.

Preferably, one of the redundant nodes is determined to have each of its substripes dependent on exactly k substripes of source data and the substripes of the redundant node are generated in dependence on all of the α×k substripes of source data.

Preferably, said determining of each of one or more of the substripes of at least one of the redundant nodes to be further dependent on at least one further substripe of source data that it is not currently dependent on is performed for r−1 redundant nodes.

Preferably, determining each of one or more of the substripes of a redundant node to be further dependent on at least one further substripe of source data that it is not currently dependent on is performed for all of the substripes of the node.

Preferably, the method further comprises performing a balanced selection of the substripes that the redundant nodes are further dependent on such that substantially the same number of read operations are required to recover each source node.

Preferably, the method is computer-implemented.

Preferably, the determined systematic coding technique is MDS.

Preferably, the combining of substripes of source data to generate a substripe of a redundant node is by linear combinations over finite fields.

Preferably, the systematic coding technique is an erasure resilient systematic coding technique.

Preferably, (k/r) is an integer.

Preferably, said step of determining each of one or more of the substripes of at least one of the redundant nodes to be further dependent on at least one further substripe of source data that it is not currently dependent on is performed in accordance with any of a random determination, a pseudo random determination, a pre-determined technique and/or an algorithm.

Preferably, when determining each of one or more of the substripes of a redundant node to be further dependent on at least one further substripe of source data that it is not currently dependent on, the selection of each further substripe of source data is independent from the order of writing and reading the previous substripes of source data.

Preferably:
said step of determining source data nodes comprises determining k source data nodes {d₁, d₂, . . . , dₖ} where each data node dⱼ comprises an indexed set of α substripes {a_{1,j}, a_{2,j}, . . . , a_{α,j}} as a two-dimensional array
Data with α rows and k columns such that

$$Data = [ \begin{matrix}{a}_{1 , 1} & {a}_{1 , 2} & … & {a}_{1 , k} \\ {a}_{2 , 1} & {a}_{2 , 2} & … & {a}_{2 , k} \\ ⋮ & ⋮ & ⋱ & ⋮ \\ {a}_{α , 1} & {a}_{α , 2} & … & {a}_{α , k}\end{matrix} ] ;$$

and
the generation of the redundant nodes comprises:
determining r redundant data nodes {p₁, p₂, . . . , pᵣ} where each redundant node pₗ, where 1≤l≤r, comprises of an indexed set of α substripes {p_{1,l}, p_{2,l}, . . . , p_{α,l}};
determining r two-dimensional index arrays P₁, . . . , Pᵣ;
determining the index array for P₁ to have α rows and k columns, where each cell in P₁ is a pair of indexes with the following values:

$${P}_{1} = [ \begin{matrix}( 1 , 1 ) & ( 1 , 2 ) & … & ( 1 , k ) \\ ( 2 , 1 ) & ( 2 , 2 ) & … & ( 2 , k ) \\ ⋮ & ⋮ & ⋱ & ⋮ \\ ( α , 1 ) & ( α , 2 ) & … & ( α , k )\end{matrix} ] ;$$

determining the index arrays P₂, . . . , Pᵣ to have α rows and k+m columns, and where each cell in P₁, where 2≤l≤r, is a pair of indexes with the following values:

$${P}_{l} = [ \begin{matrix}( 1 , 1 ) & ( 1 , 2 ) & … & ( 1 , k ) & ( ? ,?) & … & ( ? ,?) \\ ( 2 , 1 ) & ( 2 , 2 ) & … & ( 2 , k ) & ( ? ,?) & … & ( ? ,?) \\ ⋮ & ⋮ & ⋱ & ⋮ & ⋮ & ⋱ & ( ? ,?) \\ ( α , 1 ) & ( α , 2 ) & … & ( α , k ) & ( ? ,?) & … & ( ? ,?)\end{matrix} ] ,$$

where the pairs with values (?,?) are further determined according to an algorithm; and
for each of the redundant nodes {p₁, p₂, . . . , pᵣ}, determining to generate each of the substripes p_{1,l}, where 1≤i≤α and 1≤l≤r, in dependence on a combination of different source data substripes a₍ⱼ_{₁}_{,j}_{₂}₎, where the pair (j₁,j₂) is present in the i-th row of the index array Pₗ.

According to a second aspect of the invention, there is provided a method for determining how to generate a systematic code, the method comprising: receiving the code parameters n, α, k and/or r; configuring an algorithm with the received code parameters; determining, by the algorithm, how to generate a systematic code in accordance with the method of the first aspect.

Preferably, n, k, α are inputs to the algorithm and index arrays P₁, . . . , Pᵣ are outputs that define how to generate each of the redundant nodes, and wherein the algorithm performs the steps of:
initialising P₁, . . . , Pᵣ as arrays P=((i,j))_{α×k};
appending additional m=┌k/r┐ columns to P₂, . . . , Pᵣ all initialized to (0,0);

$$setting portion ← ⌈ \frac{α}{r} ⌉ ;$$

setting ValidPartitions←∅;
setting←0;
repeating the steps of:

$$setting j ← j + 1 ;$$

$$setting v ← ⌈ \frac{j}{r} ⌉ ;$$

$$setting run ← ⌈ \frac{α}{{r}^{v}} ⌉ ;$$

$$setting step ← ⌈ \frac{α}{r} ⌉ - run ;$$

determining
D_{d}_{ⱼ}=ValidPartitioning(ValidPartitions,k,r,portion,run,step,Jᵥ);
setting ValidPartitions=ValidPartitions ∪D_{d}_{ⱼ}; and
determining one D_{ρ,d}_{ⱼ}∈D_{d}_{ⱼ} such that its elements correspond to row indexes in the (k+v)-th column in one of the arrays P₂, . . . , Pᵣ, that are all zero pairs (0, 0), wherein the indexes in D_{ρ,d}_{ⱼ} are the row positions where the pairs (i,j) with indexes i∈D\D_{ρ,d}_{ⱼ} are assigned in the (k+v)-th column of P₂, . . . , Pᵣ;
until (run>1) AND (j≠0 mod r);
while j<k, performing the steps of:
   setting j←j+1;
   setting v←┌j/r┐;
   setting run←0;
   determining
   D_{d}=ValidPartitioning(ValidPartitions,k,r,portion,run,step,Jᵥ);
   setting ValidPartitions=ValidPartitions ∪ D_{d}_{ⱼ};
   determining one D_{ρ,d}_{ⱼ}∈D_{d}_{ⱼ} such that its elements correspond to row indexes in the (k+v)-th column in one of the arrays P₂, . . . , Pᵣ, that are all zero pairs (0, 0), wherein the indexes in D_{ρ,d}_{ⱼ} are the row positions where the elements (i,j) with indexes i∈D\D_{ρ,d}_{ⱼ} are assigned in the (k+v)-th column of P₂, . . . , Pᵣ; and
   when the condition j<k is no longer satisfied, outputting the determined P₁, . . . , Pᵣ;
wherein, the steps of the algorithm further comprise:
partitioning the set Nodes={d₁, . . . , dₖ} of k data disks in ┌k/r┐ disjunctive subsets

$${J}_{1} , … , {J}_{⌈ \frac{k}{r} ⌉}$$

where |Jᵥ|=r and where if r does not divide k then the last subset

$${J}_{⌈ \frac{k}{r} ⌉}$$

has k mod r elements and where

$$Nodes = {⋃}_{v = 1}^{⌈ \frac{k}{r} ⌉} {J}_{v} . ;$$

wherein the function ValidPartitioning is called by the algorithm and takes ValidPartitions, k, r, portion, run, step, Jᵥ, as inputs and outputs D_{d}_{ⱼ}=D_{1,d}_{ⱼ}, . . . , D_{r,d}_{ⱼ}; and
the ValidPartitioning function comprises the steps of:
setting D={1, 2, . . . , a};
if run≠0 then
   finding D_{d}_{ⱼ} that satisfies Condition 1 and Condition 2;
else
   finding D_{d}_{ⱼ} that satisfies Condition 2;
where Condition 1 is that at least one subset D_{ρ,d}_{ⱼ} has portion elements with runs of run consecutive elements separated with a distance between the indexes equal to step, wherein the elements of that subset correspond to row indexes in the (k+v)-th column in one of the arrays P₂, . . . , Pᵣ, that are all zero pairs (0, 0), and the distance between two elements in one node is computed in a cyclical manner such that the distance between the elements a_{α-1} and a₂ is 2; and
   Condition 2 is that a necessary condition for the valid partitioning of the elements in the systematic nodes to achieve the lowest possible repair bandwidth is

$${D}_{{d}_{{j}_{1}}} = {D}_{{d}_{{j}_{2}}}$$

for all dⱼ_{₁} and dⱼ_{₂} in Jᵥ and

$${D}_{{d}_{{j}_{1}}} \neq {D}_{{d}_{{j}_{2}}}$$

for all dⱼ_{₁} and dⱼ_{₂} systematic nodes in the system, and if portion divides α, then D_{ρ,d}_{ⱼ} for all dⱼ in the Jᵥ-th subset are disjunctive, i.e., D=∪ⱼ₌₁^{r} D_{ρ,d}_{ⱼ}={1, 2, . . . , α}.

Preferably, the combining of substripes of source data to generate a substripe p_{i,l} of the redundant node pₗ is by linear combinations over finite fields according to the index arrays P₁, . . . , Pᵣ; wherein p_{i,l}=Σc_{l,j}_{₁}_{,j}_{₂}aⱼ_{₁}_{,j}_{₂}, where 1≤i≤α, 1≤l≤r and the pair (j₁,j₂) exists in the i-th row of the index array Pₗ and co-efficient c_{l,j}_{₁}_{,j}_{₂} is some nonzero element in the finite field.

According to a third aspect of the invention, there is provided a method for storing data in a data storage system, wherein n is the total number of data storage nodes of the data storage system, k is the total number of source data nodes of the data storage system, r is the total number of redundant data nodes of the data storage system, such that n=k+r, α is the number of substripes of data in one of the nodes and each of the source data nodes and redundant data nodes comprise the same number of substripes, and wherein α satisfies the condition 1<α≤r^{m}, where m=ceiling(k/r), the method comprising: determining how to encode the source data for storing in the data storage system in dependence on the systematic coding technique of the first or second aspect; determining the redundant data by encoding the source data in accordance with the determined systematic coding technique; and storing the source data and the redundant data in the data storage nodes of the data storage system.

Preferably, the method further comprises performing a mapping operation on the source data and encoded source data such that one or more of the data storage nodes stores both source data and encoded source data.

According to a fourth aspect of the invention, there is provided a method of coding source data, the method comprising: obtaining source data; determining how to encode the source data in accordance with the systematic coding technique of any of the first aspect; and encoding the source data in accordance with the determined systematic coding technique.

Preferably, the method further comprises transferring the source data and redundant data over a network.

According to a fifth aspect of the invention, there is provided a coding technique for generating coded data from source data, the coding technique being equivalent to generating the coded data in dependence on the method of any of the first to fourth aspects.

According to a sixth aspect of the invention, there is provided a generator matrix for defining how to generate coded data from source data, the generator matrix defining a code that is equivalent to a code that has been generated by the method of any of the first to fifth aspects.

According to a seventh aspect of the invention, there is provided a generator matrix, G, for defining how to generate coded data from source data, wherein G has (α×n) rows and (α×k) columns with elements in a finite field in accordance with an above aspect, and G defines a code that is equivalent to a code that has been generated by the method of any of the first to sixth aspects and where G has the following form

$$G = [ \begin{matrix}I \\ P\end{matrix} ] ,$$

where I is an identity matrix with dimensions (α×k)×(α×k) and where P is a matrix with dimensions (α×r)×(α×k).

According to an eighth aspect of the invention, there is provided computing system configured to perform the method of any of the first fourth aspects.

According to a ninth aspect of the invention, there is provided a computer program that, when executed by a computing system, causes the computing system to perform the method of any of the first to fourth aspects.

According to a tenth aspect of the invention, there is provided a data storage system, wherein n is the total number of data storage nodes of the data storage system, k is the total number of source data nodes of the data storage system, r is the total number of redundant data nodes of the data storage system, such that n=k+r, α is the number of substripes of data in one of the nodes and each of the source data nodes and redundant data nodes comprise the same number of substripes, and wherein α satisfies the condition 1<α≤r^{m}, where m=ceiling(k/r), the data storage system configured to store data in accordance with the method of the third aspect.

According to an eleventh aspect of the invention, there is provided method of recovering a node that is one of a plurality of systematically coded source and redundant nodes, the method comprising applying a decoding method that is the inverse of the method according to any of the first to fourth aspects.

According to a twelfth aspect of the invention, there is provided a decoding technique for recovering a node that is one of a plurality of systematically coded source and redundant nodes, wherein the decoding technique is the inverse of the coding technique according to the fifth aspect.

According to a thirteenth aspect of the invention, there is provided a method of recovering one of a plurality of nodes, wherein the plurality of nodes have been coded according to the method of any of the first to fourth aspects, the method comprising: obtaining a set of

$$⌈ \frac{α}{r} ⌉$$

substripes of data from nodes of the plurality of nodes other than the node being recovered; obtaining one or more further substripes of data from nodes of the plurality of nodes other than the node being recovered; using the obtained set of

$$⌈ \frac{α}{r} ⌉$$

stripes to recover one or more substripes of the node being recovered; and recovering all of the other substripes of the node being recovered in dependence on the one or more further substripes and a re-use of the obtained set of

$$⌈ \frac{α}{r} ⌉$$

substripes.

According to a fourteenth aspect of the invention, there is provided a method for recovering one of a plurality of nodes that have been coded according to the method of any of the first to fourth aspects, the method comprising: receiving data defining how the plurality of nodes were coded; configuring an algorithm with the received data; and determining, by the algorithm, how to recover the node in dependence on data in the other of the plurality of nodes.

Preferably, the algorithm recovers a node, dₗ, by performing the following steps:
accessing and transferring

$$( k - 1 ) ⌈ \frac{α}{r} ⌉$$

elements a_{i,j} from all k−1 non-failed systematic nodes and

$$⌈ \frac{α}{r} ⌉$$

elements p_{i,1} from p₁ where i∈D_{ρ,d}_{ₗ};
repairing a_{i,l}∈D_{ρ,d}_{ₗ};
accessing and transferring

$$( r - 1 ) ⌈ \frac{α}{r} ⌉$$

elements p_{i,j} from p₂, . . . , pᵣ where i∈D_{ρ,d}_{ⱼ};
accessing and transferring from the systematic nodes the elements a_{1,j} indexed in the i-th row of the index arrays P₂, . . . , Pᵣ where i∈D_{ρ,d}_{ⱼ} that are different from said accessed and transferred

$$( k - 1 ) ⌈ \frac{α}{r} ⌉$$

elements a_{1,j} from allk−1 non-failed systematic nodes and

$$⌈ \frac{α}{r} ⌉$$

elements p_{i,1} from p₁; and
repairing a_{i,l} where i∈D\D_{ρ,d}_{ₗ};
wherein:
p₁, . . . , pᵣ are redundant data nodes with respective index arrays P₁, . . . , Pᵣ; and
the parameters of the code are as defined in the second aspect.

Preferably, the nodes are nodes of a data storage system.

According to a fifteenth aspect of the invention, there is provided a method of decoding data, the method being equivalent to decoding data in dependence on the inverse of the generator matrix generated according to the sixth or seventh aspects.

According to a sixteenth aspect of the invention, there is provided a method of reading data from a data storage system, the method comprising reading data in dependence on the method of any of claims eleventh to fifteenth aspect.

According to a seventeenth aspect, there is provided a method of recovering up to r failed nodes from a plurality of systematically coded source and redundant nodes, the method being equivalent to decoding data in dependence on the inverse of the generator matrix according to the sixth or seventh aspects.

Preferably, the method is computer-implemented.

According to an eighteenth aspect, there is provided a computing system configured to perform the method of any of the eleventh to seventeenth aspects.

According to a nineteenth aspect, there is provided a computer program that, when executed by a computing system, causes the computing system to perform the method of any of the eleventh to seventeenth aspects.

According to a twentieth aspect, there is provided a method for determining how to encode data in accordance with a systematic coding technique and encoding data in accordance with the determined systematic coding technique, the method comprising: determining the code parameters n, k, r and α, wherein n is the total number of nodes, k is the total number of source data nodes, r is the total number of redundant nodes, such that n=k+r, α is the number of substripes of data in one of the nodes and each of the source data nodes and redundant nodes comprise the same number of substripes, and wherein α is determined so that it satisfies either the condition 1<α≤r^{m} or both of the conditions α=r^{m} and (k/r) is not an integer, where m=ceiling(k/r); determining source data nodes that comprise source data that is not encoded by the systematic coding technique; for each of the redundant nodes, determining to generate each of the substripes of data in dependence on a combination of a different substripe from each of the source data nodes such that each of the substripes is generated in dependence on a combination of k substripes of source data and the α substripes of the redundant node are generated in dependence on all of the (α×k) substripes of source data; and determining each of one or more of the substripes of at least one of the redundant nodes to be further dependent on at least one further substripe of source data that it is not currently dependent on, wherein said determination comprises selecting a further substripe of source data for a redundant node to be further dependent on with the further substripe being selectable from any one of the k source nodes; and encoding data in accordance with the determined systematic coding technique.

Preferably, each of the substripes within each node is identifiable by substripe index level, i, where 1≤i≤α and i is an integer; for at least one of the redundant nodes, said determining to generate each of the substripes of data in dependence on a combination of a different substripe from each of the source data nodes comprises determining, for each substripe of said at least one of the redundant nodes, the substripe of the redundant node to be a combination of a single substripe from all of the source data nodes with the substripe of the redundant node and the substripes from each source data nodes all having the same substripe index level; and in said step of determining each of one or more of the substripes of at least one of the redundant nodes to be further dependent on at least one further substripe of source data that it is not currently dependent on, the determination comprises selecting a further substripe of source data for a redundant node to be further dependent on with the further substripe being selectable from any one of the α substripe index levels; and, preferably, the determination comprises selecting substripes from the source data nodes as further substripes of source data that one or more of the redundant nodes are further dependent on with the selection comprising at least one substripe from each of the α substripe index levels.

Preferably, for each substripe index level, there is at least one substripe of a redundant node that is dependent on an additional substripe of source data with a different substripe index level from the substripe of said at least one substripe of the redundant node.

Preferably, in said step of determining each of one or more of the substripes of at least one of the redundant nodes to be further dependent on at least one further substripe of source data that it is not currently dependent on, the determination comprises, for all but one of redundant nodes, the redundant nodes to be determined in dependence on at least one additional substripe of source data.

Preferably, in said step of determining each of one or more of the substripes of at least one of the redundant nodes to be further dependent on at least one further substripe of source data that it is not currently dependent on, the determination comprises selecting at least one substripe from each of the k source data nodes as further substripes of source data that one or more of the redundant nodes are further dependent on.

Preferably, in said step of determining each of one or more of the substripes of at least one of the redundant nodes to be further dependent on at least one further substripe of source data that it is not currently dependent on, the determination comprises selecting at least one substripe from each of the k source data nodes as further substripes of source data that one of the redundant nodes is further dependent on.

Preferably, in said step of determining each of one or more of the substripes of at least one of the redundant nodes to be further dependent on at least one further substripe of source data that it is not currently dependent on, the determination comprises, for each of two or more of the redundant nodes, selecting at least one substripe from each of the k source data nodes as further substripes of source data that the redundant node is further dependent on.

### LIST OF FIGURES

FIG. 1 shows a coding technique according to an embodiment;

FIG. 2 shows a coding technique according to an embodiment;

FIG. 3 demonstrates the advantageous performance of coding techniques according to embodiments over known coding techniques; and

FIG. 4 is a flowchart of a method for determining how to encode data in accordance with a systematic coding technique according to an embodiment.

### DESCRIPTION

Embodiments of the invention provide an advantageous systematic erasure coding technique. It is shown that a code with (n, k, d=n−1), that is constructed according to an embodiment, can have one or more of the advantageous properties of being Maximum-Distance Separable (MDS), systematic, having a flexible sub-packetisation level, providing minimum repair bandwidth, access optimality and fast decoding. A particularly advantageous property of the coding technique is the flexibility in the sub-packetisation level. That is to say, the number of substripes, i.e. sub-packets, that the data within a node is divided into can be flexibly chosen. Moreover, the sub-packetisation level can approach and/or include the lower bound as defined in the paper ‘Network coding for distributed’ by A. G. Dimakis et al, IEEE Transactions on information Theory, September 2010.

A problem with the codes disclosed in the Agarwal paper is that it is essential for k/r to be an integer in order for the codes to be constructed. This excludes the use of many widely used data storage systems, such as those with (n,k)=(14, 10).

Embodiments do not experience this problem and the codes can be constructed both when k/r is an integer and when k/r is not an integer. According to embodiments, the sub-packetisation level, α, can be equal or lower than r^{┌m┐} where m=k/r and ┌ ┐ is the ceiling function. The ceiling function is equivalently represented as ceiling( ). The ceiling function rounds a non-integer value up to the next integer.

Advantageously, the coding technique can be flexibly applied in data storage systems, such as those with (n,k)=(14, 10).

The construction of a systematic erasure code according to embodiments is described in detail below.

In a data storage system, it is quite rare for there to be a failure of a node and very rare for multiple node failures to occur simultaneously. During maintenance of the data storage system, disruption is usually minimised by only one node being offline at any given time. Accordingly, by far the most frequent requirement in a data storage system is the recovery of only one node.

The code according to embodiments is a systematic (n,k) code. That is to say, there are n nodes that store data. Of the n nodes, k of the nodes store source data that is data that has not been encoded by the erasure coding technique. There are r redundant nodes, where r=n−k. The performance of the code is presented with (n,k,d=n−1). The performance of the code is therefore demonstrated in the situation with only one node being recovered as this is by far the most common practical situation experienced. However, the code can recover up to r simultaneous failures.

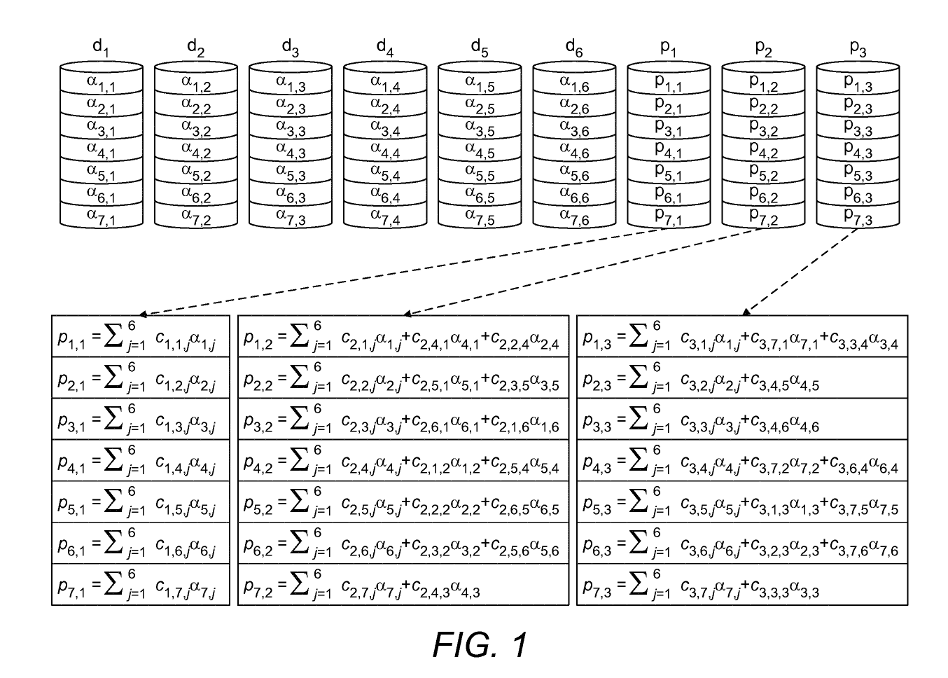

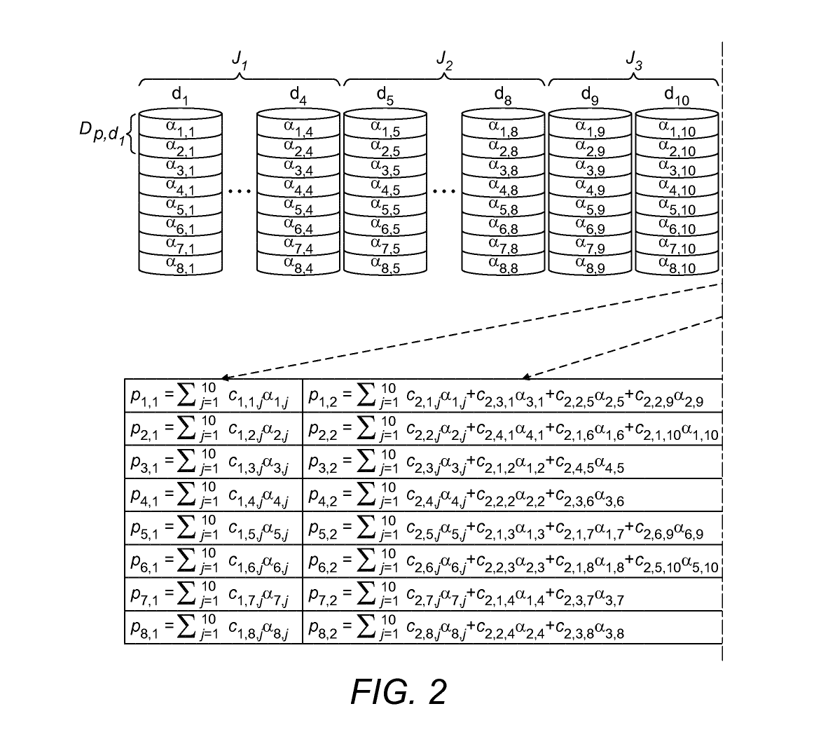

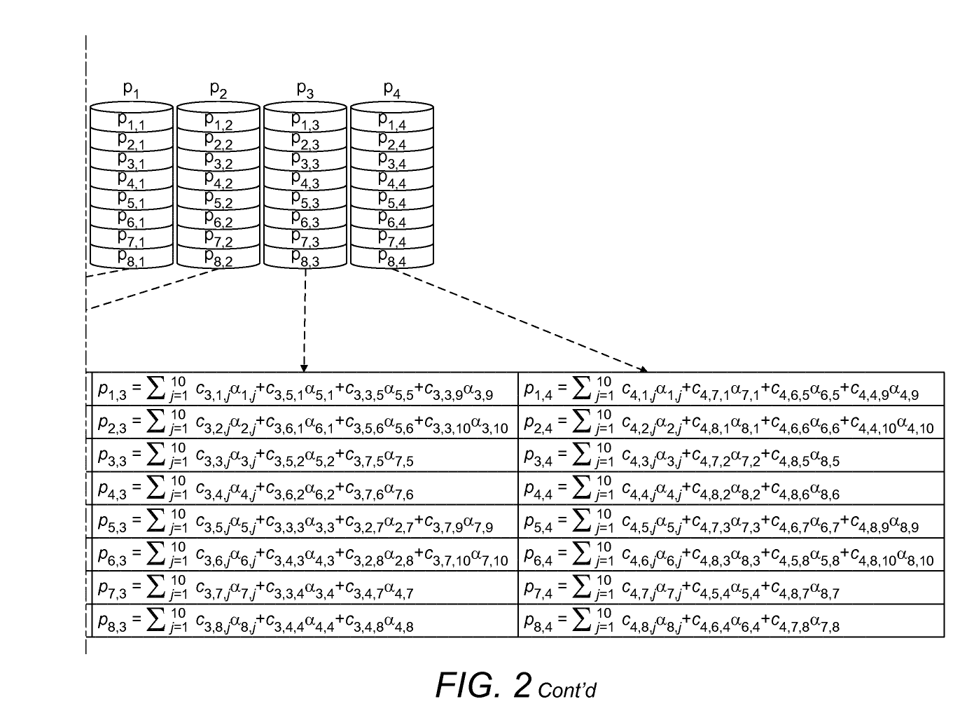

The codes according to embodiments define redundant nodes as each comprising a linear combination of all of the source data packets. At least one of the redundant nodes is defined so that its substripes are defined a linear combination of all of the substripes of source data but with each substripe of source data used only once in the construction of the substripes of the redundant node. This is the left hand redundant node in FIGS. 1 and 2.

For the other redundant nodes, one or more of their substripes are further defined as being dependent on additional substripes of the source data. There is the condition that the introduced substripes into the construction of a substripe of the redundant node are not substripes of source data that that particular substripe of the redundant node is already dependent on. The introduced substripes, and into which substripes of the redundant nodes they are added, may otherwise be selected randomly, pseudo-randomly, or according to a predetermined technique. If the introduced substripes are selected randomly, or pseudo-randomly, then preferably the determined code is tested so that it still meets the properties of being MDS. The introduction of substripes may then be repeatedly changed and tested until a code with the desired properties is obtained.

Such a definition of redundant nodes can be seen in FIGS. 1 and 2. Advantageously, the introduction of the additional substripes into the definition of redundant nodes greatly reduces the amount of data that needs to be read in order to reconstruct an unavailable node. After data has been read to reconstruct a first substripe of the node, the re-construction of the other substripes can be performed with a substantial re-use of the already read data.

A technique for constructing codes according to embodiments is set out below.

Consider a file of size B=kA_{N} symbols from a finite file F_{q} stored in k systematic nodes dⱼ of data capacity A_{N}. The capacity of a node can also be expressed by the sub-packetisation level, α, that represents the number of substripes, i.e. sub-packets, or symbols, of data stored by the node. The substripes are the smallest blocks of data transferred in operations to both encode and recover (i.e. decode) a node.

We define a code according to embodiments in the following way:

The data from the k source data nodes {d₁, d₂, . . . , dₖ} where each data node dⱼ comprises of an indexed set of α substripes {a_{1,j}, a_{2,j}, . . . , a_{α,j}} is presented as a two-dimensional array Data with α rows and k columns

$$Data = [ \begin{matrix}{a}_{1 , 1} & {a}_{1 , 2} & … & {a}_{1 , k} \\ {a}_{2 , 1} & {a}_{2 , 2} & … & {a}_{2 , k} \\ ⋮ & ⋮ & ⋱ & ⋮ \\ {a}_{α , 1} & {a}_{α , 2} & … & {a}_{α , k}\end{matrix} ] .$$

Let P=(i,j) be an index array of size α×k where α≤r^{┌m┐} and m=k/r. We define r two-dimensional index arrays P₁, . . . , Pᵣ for the r redundant data nodes {p₁, p₂, . . . , pᵣ} where each redundant node pₗ, where 1≤l≤r, comprises of an indexed set of α substripes {p_{1,l}, p_{2,l}, . . . , p_{α,l})}. The symbols p_{i,l} in the parity nodes, where 1≤i≤α and 1≤l≤r, are generated as a combination of the elements from the source data nodes a₍ⱼ_{₁}_{,j}_{₂}₎, where the pair (j₁,j₂) is present in the i-th row of the index array Pₗ. We refer to the elements of the nodes as elements or symbols and we use the terms interchangeably. The elements of each of the α rows are linearly combined with coefficients from the finite field F_{q}. These linear relations are determined according to known techniques so that they provide an MDS code, i.e., to have the property that the entire source data can be recovered from any k nodes (systematic or parity).

The index array for P₁ has a rows and k columns, and each cell in P₁ is a pair of indexes with the following values:

$${P}_{1} = [ \begin{matrix}( 1 , 1 ) & ( 1 , 2 ) & … & ( 1 , k ) \\ ( 2 , 1 ) & ( 2 , 2 ) & … & ( 2 , k ) \\ ⋮ & ⋮ & ⋱ & ⋮ \\ ( α , 1 ) & ( α , 2 ) & … & ( α , k )\end{matrix} ] .$$

The index arrays P₂, . . . , Pᵣ have α rows and k+m columns, and each cell in Pₗ, where 2≤l≤r, is a pair of indexes with the following values:

$${P}_{l} = [ \begin{matrix}( 1 , 1 ) & ( 1 , 2 ) & … & ( 1 , k ) & ( ? ,?) & … & ( ? ,?) \\ ( 2 , 1 ) & ( 2 , 2 ) & … & ( 2 , k ) & ( ? ,?) & … & ( ? ,?) \\ ⋮ & ⋮ & ⋱ & ⋮ & ⋮ & ⋱ & ( ? ,?) \\ ( α , 1 ) & ( α , 2 ) & … & ( α , k ) & ( ? ,?) & … & ( ? ,?)\end{matrix} ] ,$$

where the pairs with values (?,?) are further determined with Algorithm 1. We use the following terms and variables in Algorithm 1:

Algorithm 1 Algorithm to generate the index arrays

Input: n, k, α

Output: Index arrays P₁, . . . , Pᵣ.
1. Initialization: P₁, . . . , Pᵣ are initialized as index arrays P=(i,j)_{α×k};
2. Append additional ┌k/r┐ columns to P₂, . . . , Pᵣ all initialized to (0, 0);
3.

$$Set portion ← ⌈ \frac{α}{r} ⌉ ;$$

4. Set ValidPartitions←∅;
5. Set j←0;
6. # Phase 1
7. repeat
8. Set j←j+1;
9. Set v←┌j/r┐;
10.

$$Set run ← ⌈ \frac{α}{{r}^{v}} ⌉ ;$$

11.

$$set step ← ⌈ \frac{α}{r} ⌉ - run ;$$

12. D_{d}_{ⱼ}=ValidPartitioning(ValidPartitions, k, r, portion, run, step, jᵥ);
13. Set ValidPartitions=ValidPartitions ∪ D_{d}_{ⱼ};
14. Determine one D_{ρ,d}_{ⱼ}∈D_{d}_{ⱼ} such that its elements correspond to row indexes in the (k+v)-th column in one of the arrays P₂, . . . , Pᵣ, that are all zero pairs (0, 0);
15. The indexes in D_{ρ,d}_{ⱼ} are the row positions where the pairs (i,j) with indexes i∈D\D_{ρ,d}_{ⱼ} are assigned in the (k+v)-th column of P₂, . . . , Pᵣ;
16. until (run>1) AND (j≠0 mod r)
17. # Phase 2
18. while j<k do
19. Set j←j+1;
20. Set v←┌j/r┐;
21. Set run←0;
22. D_{d}_{ⱼ}=ValidPartitioning(ValidPartitions,k,r,portion,run,step,Jᵥ);
23. Set ValidPartitions=ValidPartitions ∪ D_{d}_{ⱼ};
24. Determine one D_{ρ,d}_{ⱼ}∈D_{d}_{ⱼ} such that its elements correspond to row indexes in the (k+v)-th column in one of the arrays P₂, . . . , Pᵣ, that are all zero pairs (0, 0);
25. The indexes in D_{ρ,d}_{ⱼ} are the row positions where the pairs (i,j) with indexes i∈D\D_{ρ,d}_{ⱼ} are assigned in the (k+v)-th column of P₂, . . . , Pᵣ;
26. end while
27. Return P₁, . . . , Pᵣ.

Algorithm 1 further calls the function ValidPartitioning where ValidPartitions, k,r, portion, run, step, Jᵥ are inputs to the function and D_{d}_{ⱼ}={D_{1,d}_{ⱼ}, . . . , D_{r,d}_{ⱼ}} is an output;

1. Set D={1, 2, . . . , α};

2. If run≠0 then

3. Find D_{d}_{ⱼ} that satisfies Condition 1 and Condition 2;

4. Else

5. Find D_{d}_{ⱼ} that satisfies Condition 2;

6. End if

7. Return D_{d}_{ⱼ};

where P₁, . . . , Pᵣ and α are global variables;

The above algorithm receives as inputs n, k, α. The input n is typically the largest number of available nodes for storing source data and redundant data in a data storage system. The input k, which is the number of nodes storing source data, is a matter of design choice. Decreasing the value of k increases the number of nodes that can be recovered but also increases the storage overhead. The input α is a matter of design choice. It was shown in the Agarwal paper that, under specific conditions, if α had certain specific values determined by n and k then improvements were made over RS codes in which α=1.

Embodiments advantageously allow α to be flexibly chosen. The choice of ac may be motivated by a value that is particularly appropriate for the underlying hardware of the data storage system and/or achieving performance gains over RS coding.

The output of the algorithm are index arrays that determine the way of combining substripes of source data to form all of the redundant nodes, also referred to as parity nodes, of a data storage system.

The terms and variables in Algorithm 1 and the function ValidPartitioning are described further below:
partitioning the set Nodes={d₁, . . . , dₖ} of k nodes in ┌k/r┐ disjunctive subsets

$${J}_{1} , … , {J}_{⌈ \frac{k}{r} ⌉}$$

where |Jᵥ|=r (if r does not divide k then the last subset

$${J}_{⌈ \frac{k}{r} ⌉}$$

has k mod r elements) and

$$Nodes = {⋃}_{v = 1}^{⌈ \frac{k}{r} ⌉} {J}_{v} .$$

Embodiments include this partitioning being any selection of k nodes, including random selections. Without loss of generality we use the natural ordering as follows:

$${J}_{1} = \{ {d}_{1} , … , {d}_{r} \} , {J}_{2} = \{ {d}_{r + 1} , … , {d}_{2 r} \} , … , {J}_{⌈ \frac{k}{r} ⌉} = \{ {d}_{⌊ \frac{k}{r} ⌋ \times r + 1} , … , {d}_{k} \} .$$

Each node dⱼ comprises an indexed set of α symbols {a_{1,j} a_{2,j}, . . . , a_{α,j}};

$$portion = ⌈ \frac{α}{r} ⌉ ,$$

the set of all symbols in dⱼ is partitioned in disjunctive subsets where at least one subset has portion number of elements.
The algorithm has two Phases. Phase 1 ends when the value of run becomes 1 and the indexes of all nodes from a specific Jᵥ have been scheduled. In Phase 2, the indexes from the remaining nodes are scheduled in the index arrays.

$$run = ⌈ \frac{α}{{r}^{v}} ⌉ ,$$

for values of

$$v ϵ \{ 1 , … , ⌈ \frac{k}{r} ⌉ \}$$

$$step = ⌈ \frac{α}{r} ⌉ - run ,$$

for the subsequent (k+v)-th column, where

$$v ∈ \{ 1 , … , ⌈ \frac{k}{r} ⌉ \} ,$$

the scheduling of the indexes corresponding to the nodes in Jᵥ is done in subsets of indexes from a valid partitioning.
A valid partitioning D_{d}_{ⱼ}={D_{1,d}_{ⱼ}, . . . , D_{r,d}_{ⱼ}} of a set of indexes D={1, 2, . . . , α}, where the i-th symbol in dⱼ is indexed by i in D, is a partitioning in r disjunctive subsets D_{d}_{ⱼ}=∪_{ρ=1}^{r} D_{ρ,d}_{ⱼ}. If r divides α, then the valid partitioning for all nodes in Jᵥ is equal. If r does not divide α, then the valid partitioning has to contain at least one subset D_{ρ,d}_{ⱼ} with portion pairs that correspond to row indexes in the (k+v)-th column in one of the arrays P₂, . . . , Pᵣ, that are all zero pairs.
Condition 1: At least one subset D_{ρ,d}_{ⱼ} has portion pairs with runs of run consecutive elements separated with a distance between the indexes equal to step. The elements of that subset correspond to row indexes in the (k+v)-th column in one of the arrays P₂, . . . , Pᵣ, that are all zero pairs (0, 0). The distance between two elements in one node is computed in a cyclical manner, i.e., the distance between the elements a_{α-1} and a₂ is 2; Condition 2: A necessary condition for the valid partitioning of the index pairs in the systematic nodes to achieve the lowest possible repair bandwidth is

$${D}_{{d}_{{j}_{1}}} = {D}_{{d}_{{j}_{2}}}$$

for all dⱼ_{₁} and dⱼ_{₂} in Jᵥ and

$${D}_{{d}_{{j}_{1}}} \neq {D}_{{d}_{{j}_{2}}}$$

for all dⱼ_{₁} and dⱼ_{₂} systematic nodes in the system. If portion divides α, then D_{ρ,d}_{ⱼ} for all dₕ in the Jᵥ-th subset are disjunctive, i.e., D=∪ⱼ₌₁^{r} D_{ρ,d}_{ⱼ}={1, 2, . . . , α}.

The corresponding algorithm for the repair, i.e. recovery, of a single systematic node dₗ is given in Algorithm 2. A set of

$$⌈ \frac{α}{r} ⌉$$

symbols are accessed and transferred from each of the n−1 non-failed nodes. If α≠r^{┌m┐}, where

$$m = \frac{k}{r} ,$$

then additional elements may be required as described in Step 4 of Algorithm 2. Note that when reading data in from a data storage system, specific elements of the data are transferred from their nodes just once and then stored in a buffer. For every subsequent use of that element the element is read from the buffer and a further transfer operation to obtain the element from the data storage system is not required. Advantageously, the amount of read data is less than, for example, that required for RS coding.

Algorithm 2 Repair of a systematic node dₗ
1. Access and transfer

$$( k - 1 ) ⌈ \frac{α}{r} ⌉$$

elements a_{i,j} from allk−1 non-failed systematic nodes and

$$⌈ \frac{α}{r} ⌉$$

elements p_{i,1} from p₁ where i∈D_{ρ, d}_{ₗ};
2. Repair a_{i,l}∈D_{ρ,d}_{ₗ};
3. Access and transfer

$$( r - 1 ) ⌈ \frac{α}{r} ⌉$$

elements p_{i,j} from p₂, . . . , pᵣ where i∈D_{ρ,d}_{ⱼ};
4. Access and transfer from the systematic nodes the elements a_{i,j} with indexes listed in the i-th row of the index arrays P₂, . . . , Pᵣ where i∈D_{ρ,d}_{ⱼ} that have not been read in step 1;
5. Repair a_{i,l} where i∈D\D_{ρ,d}_{ₗ};

Proposition 1: The repair bandwidth β to repair a single systematic node is bounded between the following values (lower and upper bound of the repair traffic):

$$\frac{( n - 1 )}{r} \leq β \leq \frac{( n - 1 )}{r} + \frac{( r - 1 )}{α} ⌈ \frac{α}{r} ⌉ ⌈ \frac{k}{r} ⌉$$

The optimality of the proposed Algorithm is captured in the following Proposition.

Proposition 2: The indexes (i, l) of the elements a_{i,l} where i∈D\D_{ρ,d}_{ₗ} for each group of r systematic nodes are scheduled in one of the

$$⌈ \frac{k}{r} ⌉$$

additional columns in the index arrays P₂, . . . Pᵣ.

Next we show that there always exists a set of non-zero coefficients from F_{q} in the linear combinations so that the code is MDS. We adopt Theorem 4.1 in the Agarwal paper:

Theorem 1: There exists a choice of non-zero coefficients c_{l,i,j} where l=1, . . . , r, i=1, . . . , α and j=1, . . . , k from F_{q} such that the code is MDS if

$$q \geq ( \begin{matrix}n \\ k\end{matrix} ) r α .$$

Examples of the generation of a code according to the Algorithms presented herein are provided below. Embodiments are first demonstrated with a (9,6,8) code that has the unusual sub-packetisation level equal of 7. Embodiments are then demonstrated with a (14, 10, 9) code. This is a practical code that is used, for example, in the data storage system of Facebook™.

The first embodiment constructs a (n,k,d)=(9,6,8) code. The optimal sub-packetisation level to achieve the lower bound of the repair traffic given in the Agarwal paper for this code is 3^{┌6/3┐}=9 and this is the only sub-packetisation level possible with the codes in the Agarwal paper. The present embodiment demonstrates the use of a flexible sub-packetisation level with α=7.

The algorithms disclosed herein allow any sub-packetisation level to be used that is less than or equal to r^{┌k/r┐}.

FIG. 1 shows the structure of the systematic code generated according to the embodiment. The nodes d₁, . . . , d₆ are the systematic nodes, also referred to as source data nodes, and store source data. The nodes p₁, p₂ and p₃ are the redundant nodes, also referred to as parity nodes. The file size B is 42 symbols. The elements of p₁ are linear combinations of the row elements from the systematic nodes multiplied by coefficients from a finite field, while the parity nodes p₂ and p₃ have further elements besides the row sum. The embodiment schedules the indexes of the elements of the systematic nodes that do not belong to D_{ρ,d}_{ⱼ} at portion=3 positions on the (6+v)-th column, v=1, 2, of P₂ and P₃.

The following steps are performed to determine the further elements in the parity nodes p₂ and p₃ besides the row sum.
1. Initialize P₁, P₂, P₃ as arrays P=(i,j)_{7×6}.
2. Append additional ┌6/3┐=2 columns to P₂ and P₃ initialized to (0, 0).
3. We use the notation D_{ρ,d}_{ⱼ}=1, . . . , 6, to denote the subset with its elements corresponding to row indexes in the (6+v)-th column, v=1, 2, in one of the arrays P₂ and P₃, that are all zero values (0, 0).
4. Set portion equal to 3 and ValidPartitions to an empty set.
5. # Phase 1:
   For the systematic nodes d₁, d₂ and d₃ in J₁, run is equal to 3 and step is equal to 0,
6. We call the function ValidPartitioning( ) with appropriate parameters for this phase. In this phase both Condition 1 and Condition 2 have to be fulfilled. For the node d₁ as the output from the function ValidPartitioning( ) we get D_{d}_{₁}={{1,2,3}, {4,5,6}, {7}}. Further on with steps 14 and 15 of Algorithm 1 we determine D_{ρ,d}_{₁}={1, 2, 3}. This is due to the fact that the first 3 zero elements in the 7-th column of P₂ are at the positions (i, 7) where i=1, 2, 3. Note that the run length is 3 and the distance between the indexes is 0. The i indexes of the remaining pairs (i, 1) where i=4, . . . , 7 belong to 2 other subsets D\D_{ρ,d}_{₁}, i.e., D_{2,d}_{₁}={4, 5, 6} and D_{3,d}_{₁}={7}. The pairs (i, 1) for i∈D\D_{ρ,d}_{₁} are added in the 7-th column of P₂, P₃. Similarly, for the node d₂ as the output from the function ValidPartitioning( ) we get D_{d}_{₁}={{1,2,3}, {4,5,6}, {7}} and after steps 14 and 15 in Algorithm 1 we get D_{ρ,d}_{₂}={4, 5, 6}. For the node d₃ we get D_{d}_{₃}={{1,2,3}, {5,6,7}, {4}} and D_{ρ,d}_{₃}={5, 6, 7}.
7. At the end of this phase ValidPartitions={{1,2,3}, {4,5,6}, {7}, {5,6,7}, {4}}
8. At the end of this phase a snapshot from three index arrays P₁, P₂, P₃ is like this:

$${P}_{1} = [ \begin{matrix}( 1 , 1 ) & ( 1 , 2 ) & ( 1 , 3 ) & ( 1 , 4 ) & ( 1 , 5 ) & ( 1 , 6 ) \\ ( 2 , 1 ) & ( 2 , 2 ) & ( 2 , 3 ) & ( 2 , 4 ) & ( 2 , 5 ) & ( 2 , 6 ) \\ ( 3 , 1 ) & ( 3 , 2 ) & ( 3 , 3 ) & ( 3 , 4 ) & ( 3 , 5 ) & ( 3 , 6 ) \\ ( 4 , 1 ) & ( 4 , 2 ) & ( 4 , 3 ) & ( 4 , 4 ) & ( 4 , 5 ) & ( 4 , 6 ) \\ ( 5 , 1 ) & ( 5 , 2 ) & ( 5 , 3 ) & ( 5 , 4 ) & ( 5 , 5 ) & ( 5 , 6 ) \\ ( 6 , 1 ) & ( 6 , 2 ) & ( 6 , 3 ) & ( 6 , 4 ) & ( 6 , 5 ) & ( 6 , 6 ) \\ ( 7 , 1 ) & ( 7 , 2 ) & ( 7 , 3 ) & ( 7 , 4 ) & ( 7 , 5 ) & ( 7 , 6 )\end{matrix} ]$$

$${P}_{2} = [ \begin{matrix}( 1 , 1 ) & ( 1 , 2 ) & ( 1 , 3 ) & ( 1 , 4 ) & ( 1 , 5 ) & ( 1 , 6 ) & ( 4 , 1 ) & ( 0 , 0 ) \\ ( 2 , 1 ) & ( 2 , 2 ) & ( 2 , 3 ) & ( 2 , 4 ) & ( 2 , 5 ) & ( 2 , 6 ) & ( 5 , 1 ) & ( 0 , 0 ) \\ ( 3 , 1 ) & ( 3 , 2 ) & ( 3 , 3 ) & ( 3 , 4 ) & ( 3 , 5 ) & ( 3 , 6 ) & ( 6 , 1 ) & ( 0 , 0 ) \\ ( 4 , 1 ) & ( 4 , 2 ) & ( 4 , 3 ) & ( 4 , 4 ) & ( 4 , 5 ) & ( 4 , 6 ) & ( 1 , 2 ) & ( 0 , 0 ) \\ ( 5 , 1 ) & ( 5 , 2 ) & ( 5 , 3 ) & ( 5 , 4 ) & ( 5 , 5 ) & ( 5 , 6 ) & ( 2 , 2 ) & ( 0 , 0 ) \\ ( 6 , 1 ) & ( 6 , 2 ) & ( 6 , 3 ) & ( 6 , 4 ) & ( 6 , 5 ) & ( 6 , 6 ) & ( 3 , 2 ) & ( 0 , 0 ) \\ ( 7 , 1 ) & ( 7 , 2 ) & ( 7 , 3 ) & ( 7 , 4 ) & ( 7 , 5 ) & ( 7 , 6 ) & ( 4 , 3 ) & ( 0 , 0 )\end{matrix} ]$$

$${P}_{3} = [ \begin{matrix}( 1 , 1 ) & ( 1 , 2 ) & ( 1 , 3 ) & ( 1 , 4 ) & ( 1 , 5 ) & ( 1 , 6 ) & ( 7 , 1 ) & ( 0 , 0 ) \\ ( 2 , 1 ) & ( 2 , 2 ) & ( 2 , 3 ) & ( 2 , 4 ) & ( 2 , 5 ) & ( 2 , 6 ) & ( 0 , 0 ) & ( 0 , 0 ) \\ ( 3 , 1 ) & ( 3 , 2 ) & ( 3 , 3 ) & ( 3 , 4 ) & ( 3 , 5 ) & ( 3 , 6 ) & ( 0 , 0 ) & ( 0 , 0 ) \\ ( 4 , 1 ) & ( 4 , 2 ) & ( 4 , 3 ) & ( 4 , 4 ) & ( 4 , 5 ) & ( 4 , 6 ) & ( 7 , 2 ) & ( 0 , 0 ) \\ ( 5 , 1 ) & ( 5 , 2 ) & ( 5 , 3 ) & ( 5 , 4 ) & ( 5 , 5 ) & ( 5 , 6 ) & ( 1 , 3 ) & ( 0 , 0 ) \\ ( 6 , 1 ) & ( 6 , 2 ) & ( 6 , 3 ) & ( 6 , 4 ) & ( 6 , 5 ) & ( 6 , 6 ) & ( 2 , 3 ) & ( 0 , 0 ) \\ ( 7 , 1 ) & ( 7 , 2 ) & ( 7 , 3 ) & ( 7 , 4 ) & ( 7 , 5 ) & ( 7 , 6 ) & ( 3 , 3 ) & ( 0 , 0 )\end{matrix} ]$$

9. # Phase 2:
10. For the systematic nodes d₄, d₅ and d₆ in J₂ set run equal to 0. Now, when we call the function ValidPartitioning( ) with appropriate parameters for this phase, only the Condition 2 has to be fulfilled. For the node d₄ as the output from the function ValidPartitioning( ) we get D_{d}_{₄}={{1,4,7}, {2,5}, {3,6}} and after steps 24 and 25 in Algorithm 1 we get D_{ρ,d}_{₄}={1, 4, 7}. A similar steps and outputs are obtained for d₅ and d₆ and they are: D_{ρ,d}_{₅}={2, 5, 1} and D_{ρ,d}_{₆}={3, 6, 2}.
11. At the end of this phase ValidPartitions={{1,2,3}, {4,5,6}, {7}, {5,6,7}, {4}, {1,4,7}, {2,5}, {3,6}, {2,5,1}, {3,6,2}}
12. At the end of this phase a snapshot from three index arrays P₁, P₂, P₃ is like this:

$${P}_{1} = [ \begin{matrix}( 1 , 1 ) & ( 1 , 2 ) & ( 1 , 3 ) & ( 1 , 4 ) & ( 1 , 5 ) & ( 1 , 6 ) \\ ( 2 , 1 ) & ( 2 , 2 ) & ( 2 , 3 ) & ( 2 , 4 ) & ( 2 , 5 ) & ( 2 , 6 ) \\ ( 3 , 1 ) & ( 3 , 2 ) & ( 3 , 3 ) & ( 3 , 4 ) & ( 3 , 5 ) & ( 3 , 6 ) \\ ( 4 , 1 ) & ( 4 , 2 ) & ( 4 , 3 ) & ( 4 , 4 ) & ( 4 , 5 ) & ( 4 , 6 ) \\ ( 5 , 1 ) & ( 5 , 2 ) & ( 5 , 3 ) & ( 5 , 4 ) & ( 5 , 5 ) & ( 5 , 6 ) \\ ( 6 , 1 ) & ( 6 , 2 ) & ( 6 , 3 ) & ( 6 , 4 ) & ( 6 , 5 ) & ( 6 , 6 ) \\ ( 7 , 1 ) & ( 7 , 2 ) & ( 7 , 3 ) & ( 7 , 4 ) & ( 7 , 5 ) & ( 7 , 6 )\end{matrix} ]$$

$${P}_{2} = [ \begin{matrix}( 1 , 1 ) & ( 1 , 2 ) & ( 1 , 3 ) & ( 1 , 4 ) & ( 1 , 5 ) & ( 1 , 6 ) & ( 4 , 1 ) & ( 2 , 4 ) \\ ( 2 , 1 ) & ( 2 , 2 ) & ( 2 , 3 ) & ( 2 , 4 ) & ( 2 , 5 ) & ( 2 , 6 ) & ( 5 , 1 ) & ( 3 , 5 ) \\ ( 3 , 1 ) & ( 3 , 2 ) & ( 3 , 3 ) & ( 3 , 4 ) & ( 3 , 5 ) & ( 3 , 6 ) & ( 6 , 1 ) & ( 1 , 6 ) \\ ( 4 , 1 ) & ( 4 , 2 ) & ( 4 , 3 ) & ( 4 , 4 ) & ( 4 , 5 ) & ( 4 , 6 ) & ( 1 , 2 ) & ( 5 , 4 ) \\ ( 5 , 1 ) & ( 5 , 2 ) & ( 5 , 3 ) & ( 5 , 4 ) & ( 5 , 5 ) & ( 5 , 6 ) & ( 2 , 2 ) & ( 6 , 5 ) \\ ( 6 , 1 ) & ( 6 , 2 ) & ( 6 , 3 ) & ( 6 , 4 ) & ( 6 , 5 ) & ( 6 , 6 ) & ( 3 , 2 ) & ( 5 , 6 ) \\ ( 7 , 1 ) & ( 7 , 2 ) & ( 7 , 3 ) & ( 7 , 4 ) & ( 7 , 5 ) & ( 7 , 6 ) & ( 4 , 3 ) & ( 0 , 0 )\end{matrix} ]$$

$${P}_{3} = [ \begin{matrix}( 1 , 1 ) & ( 1 , 2 ) & ( 1 , 3 ) & ( 1 , 4 ) & ( 1 , 5 ) & ( 1 , 6 ) & ( 7 , 1 ) & ( 3 , 4 ) \\ ( 2 , 1 ) & ( 2 , 2 ) & ( 2 , 3 ) & ( 2 , 4 ) & ( 2 , 5 ) & ( 2 , 6 ) & ( 0 , 0 ) & ( 4 , 5 ) \\ ( 3 , 1 ) & ( 3 , 2 ) & ( 3 , 3 ) & ( 3 , 4 ) & ( 3 , 5 ) & ( 3 , 6 ) & ( 0 , 0 ) & ( 4 , 6 ) \\ ( 4 , 1 ) & ( 4 , 2 ) & ( 4 , 3 ) & ( 4 , 4 ) & ( 4 , 5 ) & ( 4 , 6 ) & ( 7 , 2 ) & ( 6 , 4 ) \\ ( 5 , 1 ) & ( 5 , 2 ) & ( 5 , 3 ) & ( 5 , 4 ) & ( 5 , 5 ) & ( 5 , 6 ) & ( 1 , 3 ) & ( 7 , 5 ) \\ ( 6 , 1 ) & ( 6 , 2 ) & ( 6 , 3 ) & ( 6 , 4 ) & ( 6 , 5 ) & ( 6 , 6 ) & ( 2 , 3 ) & ( 7 , 6 ) \\ ( 7 , 1 ) & ( 7 , 2 ) & ( 7 , 3 ) & ( 7 , 4 ) & ( 7 , 5 ) & ( 7 , 6 ) & ( 3 , 3 ) & ( 0 , 0 )\end{matrix} ]$$

The above demonstrates how the indexes of the substripes used to generate each of the redundant nodes of a systematic erasure code are determined according to an embodiment.

Next we demonstrate how the systematic node d₁ is recovered, according to an embodiment, in the event of this node being unavailable. First, we repair the elements a_{i,1}, i∈D_{ρ,d}_{₁}, i.e., a_{i,1} where i=1, 2, 3.

We therefore access and transfer 3 a_{i,j} elements where i=1, 2, 3 and j=2, . . . , 6 from the non-failed systematic nodes and 3 p_{i,1} elements where i=1, 2, 3 from p₁. In order to recover the rest of the elements a_{i,1}, i∈D\D_{ρ,d}_{₁}, we need to access and transfer 3 symbols p_{i,2} where i=1, 2, 3 from p₂ and 1 symbol p_{1,3} from p₃. This demonstrates that the data from d₁ can be recovered by accessing and transferring in total 22 elements from the 8 non-failed nodes. The same amount of data, 22 symbols, is needed to recover any of the other systematic nodes in the event of the failure of a single node. Accordingly, codes generated according to algorithm 1 are balanced in that the same amount of data needs to read in order to recover any one of the nodes.

In preferred embodiments, one of the redundant nodes is generated in dependence on all of the substripes of the source data nodes with all of the substripes of the redundant node comprising different substripes of the source data nodes such that no two substripes of the redundant node are generated in dependence on the same substripe of source data. The coding advantages of embodiments are realised by the generation of one or more further redundant nodes that are also generated in dependence on all of the substripes of the source data nodes but with one or more substripes within each node being generated in further dependence of source data packets such that the same substripe(s) of source data are used in the generation of different substripes of the same redundant node. This technique allows the re-use of already read data when reconstructing a node and therefore less data needs to be read than in RS coding.

FIG. 2 shows the structure of the systematic (14, 10, 13) code generated according to a second embodiment. Note that this code cannot be generated with the method presented in the Agarwal paper. The optimal sub-packetisation level to achieve the lower bound of the repair traffic given in the paper ‘Network coding for distributed’ by A. G. Dimakis et al, IEEE Transactions on information Theory, September 2010 is 4^{┌10/4┐}=64 but constructing a (14, 10, 13) code with this sub-packetisation level is not possible with the codes disclosed in the Agarwal paper.

We demonstrate the advantage of embodiments of being able to construct an access-optimal code for any sub-packetization level, thus we set α=8.

The nodes d₁, . . . , d₁₀ are the systematic nodes, also referred to as source data nodes, and store source data. The nodes p₁, p₂, p₃ and p₄ are the redundant nodes, also referred to as parity nodes. The file size B is 80 symbols. The elements of p₁ are linear combinations of the row elements from the systematic nodes multiplied by coefficients from a finite field, while the parity nodes p₂, p₃ and p₄ have extra elements besides the row sum.

The above described Algorithm 1 is used to determine the additional substripes of source data that all but one of the parity nodes is to be generated in dependence on. The embodiment schedules the elements a_{i,j} from a specific dⱼ where i∈D\D_{p,d}_{ⱼ} at portion positions in i-th row, i∈D_{p,d}_{ⱼ} and the (10+v)-th column, v=1, 2, 3 of p₂, p₃ and p₄. The determined combinations of substripes for each of the parity nodes is shown in FIG. 2.

To demonstrate the improved performance of embodiments, we compare the performance for an (14, 10) code under RS, those in the Hitchhiker paper and codes generated according to embodiments.

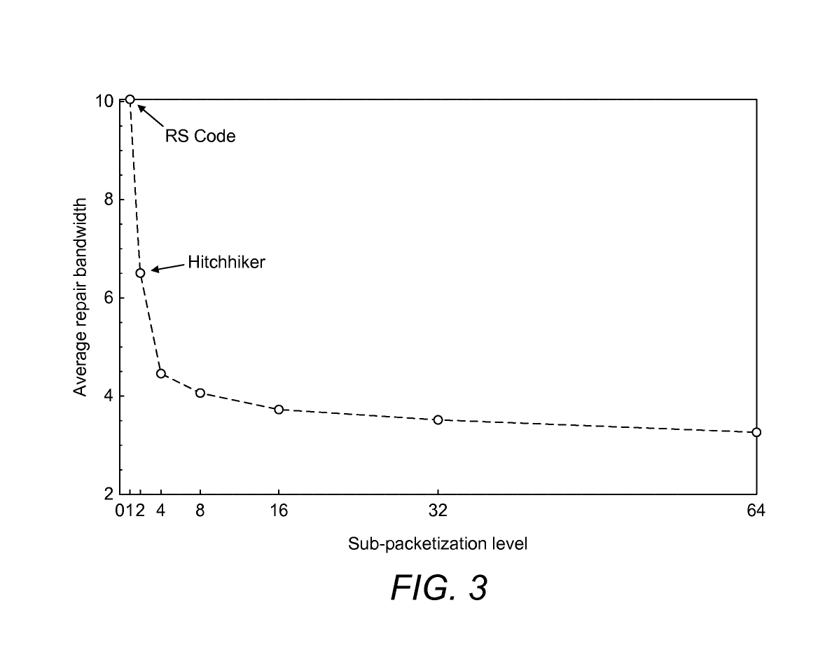

FIG. 3 depicts the correlation between the average repair bandwidth and the sub-packetisation level. Average repair bandwidth is defined as the ratio of the total repair bandwidth to repair all systematic nodes to the file size B. The average repair bandwidth is equal to the file size for a RS code and this corresponds to the value of the repair bandwidth when the sub-packetisation level is 1. A Hitchhiker code with a sub-packetisation level equal to 2 reduces the repair bandwidth by 35% from that of the RS code. The rest of the values for the average repair bandwidth are for different sub-packetisation levels and determined for the codes according to embodiments. The lowest average repair bandwidth is 3.25 and is reached for α=r^{m}=64, where m=┌k/r┐. The codes according to embodiments reduce the repair bandwidth for any systematic node by 67.5% from that of the RS code.

Embodiments therefore provide a general construction of access-optimal regenerating codes for any systematic node when the sub-packetisation level α is less than or equal to r^{m}, where m=┌k/r┐ and k/r is not restricted to being an integer. The wide range for sub-packetisation levels together with the two Phases in Algorithm 1 in the code construction lead to a high flexibility of constructing codes for different code rates and for different bottlenecks caused by underlying hardware and system configurations. The lower bound of the repair bandwidth is achieved for α=r^{┌k/r┐}, while the repair bandwidth is close the lower bound when α<r^{┌k/r┐}. The repair process of a failed systematic node is linear and highly parallelized. A set of ┌α/r┐ symbols is independently repaired first and used along with the accessed data from other nodes to repair the remaining symbols.

Codes according embodiments include codes in which k/r is an integer. For such codes, a may be less than r^{m}, where m=k/r. Embodiments do also include codes in which k/r is an integer and α is equal to r^{m}, where m=k/r. There are advantages of codes according to these embodiments over the codes disclosed in the Agarwal paper. For example, the codes according to embodiments have improved properties such as providing access optimality, fast decoding, consecutiveness of stripes and others. In addition, as described in more detail later, the techniques and algorithm disclosed herein for constructing codes according to embodiments can be used to construct a large number of codes and the codes with the most appropriate properties can be selected for a particular application.

Accordingly, the embodiment provides an advantageous structure of code. Embodiments are not limited to the construction of codes according to the specific algorithms disclosed herein and embodiments extend to any systematic erasure coding technique that determines how to generate substripes of redundant nodes in a way that improves over RS coding whilst providing advantageous flexible code construction according to embodiments.

As shown in FIGS. 1 and 2, the first of the redundant nodes is generated as a linear combination of substripes within the source data nodes. The other redundant nodes are based on a similar combination of source nodes as the first redundant node, though the linear coefficients of each node may differ. The other redundant nodes may be based on the same combination of substripes as for the first redundant node and only differ due to the additional substripes that are introduced into the combination. The algorithms presented herein determine how to generate such codes and to achieve significant advantages over RS coding. However, in practice, the addition of any additional substripes into the combination improves on RS coding so long as the introduced substripe is not a substripe that the substripe of the redundant node is already determined to be dependent on. The operation at the substripe level allows the re-use of already obtained data when recovering an unavailable node and thereby reduces the amount of data that needs to be read from RS coding.

In particular, when determining which additional substripes are included in a combination for generating a substripe of a redundant node, there is a lot of flexibility on which substripes can be included. For example, the additional substripes that are determined for inclusion in a combination are not restricted by the condition of being dependent on message symbols from previous instances. That is to say, the selection of each additional substripe is independent from the order of writing and reading the previous substripes of source data. Preferably, the selection of each additional substripe is also independent from the previous determinations of substripe combinations. For example, an additional substripe may be selected for any of the substripe levels of any of the source nodes. This flexibility allows codes with a wide range of properties may be generated so as to realise, for example, an advantageous repair bandwidth.

Particularly preferred determinations of additional substripes for generating one or more substripes of a redundant node in dependence on include one or more of the following:
At least one additional source data substripe being selectable from any one of the source nodes;
At least one additional source data substripe from each substripe index level being included in the redundant nodes, wherein each of the substripes within each node is identifiable by substripe index level, i, where 1≤i≤α and i is an integer;
For each substripe index level, there is at least one substripe of a redundant node that is dependent on an additional substripe of source data with a different substripe index level from the substripe of said at least one substripe of the redundant node;
At least one additional source data substripe being selectable from any one of the substripe index levels;
for all but one of redundant nodes, the redundant nodes to be determined in dependence on at least one additional substripe of source data;
selecting at least one substripe from each of the source data nodes as further substripes of source data that one or more of the redundant nodes are further dependent on;
selecting at least one substripe from each of the source data nodes as further substripes of source data that one of the redundant nodes is further dependent on; and
for each of two or more of the redundant nodes, selecting at least one substripe from each of the source data nodes as further substripes of source data that the redundant node is further dependent on.

Accordingly, embodiments provide a systematic erasure coding technique with a flexible sub-packetisation level that improves on RS coding. Improvements are made by determining each of one or more of the substripes of at least one other redundant node than the first redundant node to be further dependent on at least one further substripe of source data that it is not currently dependent on.

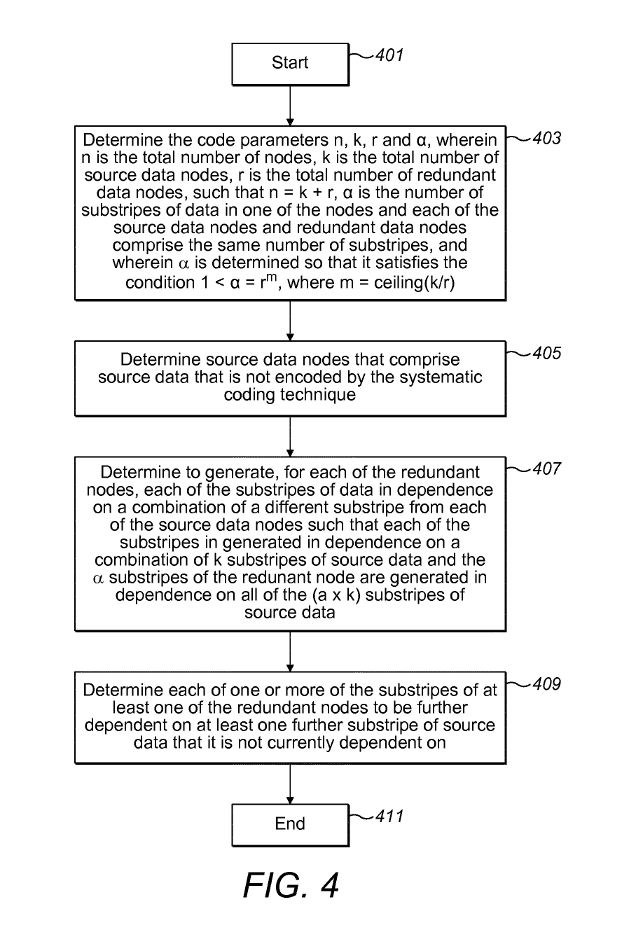

FIG. 4 is a flowchart of a method for determining how to encode data in accordance with a systematic coding technique according to an embodiment.

In step 401, the process begins.

In step 403, the code parameters n, k, r and α are determined, wherein n is the total number of nodes, k is the total number of source data nodes, r is the total number of redundant data nodes, such that n=k+r, α is the number of substripes of data in one of the nodes and each of the source data nodes and redundant data nodes comprise the same number of substripes, and wherein α satisfies the condition 1<α≤r^{m}, where

$$m = ⌈ \frac{k}{r} ⌉ .$$

In step 405, source data nodes are determined that comprise source data that is not encoded by the systematic erasure coding technique.

In step 407, it is determined to generate, for each of the r redundant nodes, each of the α substripes of data in dependence on a combination of a different substripe from each of the k source data nodes such that each of the ac substripes is generated in dependence on a combination of k substripes of source data and the α substripes of the redundant node are generated in dependence on all of the α×k substripes of source data.

In step 409, each of one or more of the ac substripes of at least one of the r redundant nodes are determined to be further dependent on at least one further substripe of source data that it is not currently dependent on.

In step 411, the process ends.

Embodiments of the invention also include a number of modifications and variations to the embodiments as described above.

Preferably, each coding of source and redundant nodes that are generated according to embodiments is tested to determine that it has the property of being MDS. This preferably is part of an iterative process with each iteration changing one or more of the coefficients of one of the additional substripes of source data that a redundant node is made to be dependent on, the actual substripe of source data or the substripe of the redundant node that an additional substripe is added to. The iterative process would be stopped as soon as the generator matrix was determined to be MDS. Advantageously, the coding of source and redundant nodes according to this embodiment is always MDS.

An advantageous property of the coding of source and redundant nodes according to embodiments is that, when the coding is expressed as a generator matrix, if all of the columns of the generator matrix are linearly independent, the generator matrix defines an MDS coding technique. The process of determining if a code is MDS is therefore straightforward for a skilled person to implement.

TABLE 1

| Code (n, k) | k | r |
|---|---|---|
| (6, 3) | 3 | 3 |
| (9, 6) | 6 | 3 |
| (12, 9) | 9 | 3 |
| (14, 11) | 11 | 3 |
| (15, 12) | 12 | 3 |
| (16, 13) | 13 | 3 |
| (17, 13) | 14 | 3 |
| (18, 14) | 14 | 3 |
| (19, 16) | 16 | 3 |
| (20, 17) | 17 | 3 |
| (23, 20) | 20 | 3 |
| (24, 21) | 21 | 3 |
| (8, 4) | 4 | 4 |
| (9, 5) | 5 | 4 |
| (10, 6) | 6 | 4 |
| (12, 8) | 8 | 4 |
| (14, 10) | 10 | 4 |
| (15, 11) | 11 | 4 |
| (16, 12) | 12 | 4 |
| (18, 14) | 14 | 4 |
| (19, 15) | 15 | 4 |
| (20, 16) | 16 | 4 |
| (22, 18) | 18 | 4 |
| (23, 19) | 19 | 4 |
| (24, 20) | 20 | 4 |
| (25, 21) | 21 | 4 |
| (26, 22) | 22 | 4 |
| (28, 24) | 24 | 4 |
| (30, 26) | 26 | 4 |
| (32, 28) | 28 | 4 |
| (34, 30) | 30 | 4 |
| (10, 5) | 5 | 5 |
| (12, 7) | 7 | 5 |
| (15, 10) | 10 | 5 |
| (20, 15) | 15 | 5 |
| (25, 20) | 20 | 5 |
| (30, 35) | 25 | 5 |
| (35, 30) | 30 | 5 |
| (40, 35) | 35 | 5 |
| (45, 40) | 40 | 5 |
| (12, 6) | 6 | 6 |
| (15, 9) | 9 | 6 |
| (18, 12) | 12 | 6 |
| (19, 13) | 13 | 6 |
| (20, 14) | 14 | 6 |
| (26, 20) | 20 | 6 |
| (30, 24) | 24 | 6 |
| (31, 25) | 25 | 6 |
| (46, 40) | 40 | 6 |
| (14, 7) | 7 | 7 |
| (27, 7) | 20 | 7 |
| (16, 8) | 8 | 8 |
| (20, 12) | 12 | 8 |
| (28, 20) | 20 | 8 |
| (32, 24) | 24 | 8 |
| (48, 40) | 40 | 8 |

Example values for k and r for implementation in embodiments are shown in Table 1. The codes shown in Table 1 cover many common disk array sizes. Particularly preferable are codes with k a lot greater than r. These are the most efficient as only one source node reconstruction at a particular time is likely to be required. The underlying finite field may be GF(256). Embodiments also include using more complex GF(256) operations and this would allow larger configurations to be realised. The codes according to embodiments can be constructed over any GF field of size GF(2ⁿ) so long as n is large enough for a MDS erasure code to be generated. A typical implementation would have a GF field size of GF(16) or GF(256).

Embodiments are particularly appropriate for generating data for storage in nodes of a data storage system. In a typical implementation of such a system the number of redundant data nodes is a lot fewer than the number of source data nodes. In a preferred implementation of an embodiment in a data storage system, the number of substripes in each node is less than or equal to r^{m}, where m=┌k/r┐.

A particularly advantageous property of the codes according to embodiments is that there is a lot of flexibility when generating codes with the same parameters of k, r, α. That is to say, a large number of different codes can be generated with all of the codes being designed for systems with the same number of source nodes, the same number of redundant nodes and the same sub-packetisation level. However, the generated codes will differ in their properties and by selecting codes for use that have the most appropriate properties for a particular application the used codes can be optimised for the particular application. Examples of properties that the codes can be optimised with respect to are repair bandwidth, the number of Input/Output operations (i.e. the number of reads and writes) and the latency of the repair. The code optimisation with respect to a particular property may be performed as part of a stand alone iterative process for optimising MDS codes, or the code optimisation may be performed within the above-described iterative process for determining if a generator matrix is for an MDS code.

The actual generation of coded data in dependence on source data according to embodiments can be performed with known techniques and using known hardware. The processes required to use the techniques according to embodiments to generate a plurality of source nodes and redundant nodes in a data storage system/network of a data centre storing the coded data would be a straightforward task for the skilled person. The skilled person would also be able to use known hardware to reconstruct one or more source nodes in order to implement embodiments.

The nodes according to embodiments include single data disks, or drives, or groups or data disks, or drives. A node includes any form of data storage element, a part of such an element or multiple such elements. In particular, a node can be any logical entity where data can be stored, and can be anything from a whole, a group of or parts of physical storage devices or locations including but not limited to memory based storage devices such as RAM and SSDs, hard drives, tape storage, optical storage devices, servers and data centers. The method according to embodiments may be performed within a single SSD disk. The method according to embodiments may be performed between chips inside a SSD, or between banks inside (flash) chips.

The coding technique according to embodiments can therefore be used for each file/object/entity of data being stored on storage nodes/storage mediums. For example, say that the storage nodes comprise 14 hard drives and the encoding scheme has 10 data nodes and four redundancy nodes. The coding technique of embodiments can be applied to each file being stored on the hard drives so that each file is split into 10 segments and four redundancy segments of data is generated for each file. The encoding pattern is therefore found multiple times in the stored data (as many times as there are files being stored) on the storage nodes and not necessarily once for all of the storage nodes. The pattern is therefore repeated for each file.

The storage of the data in a data storage system is not limited to the data storage system having nodes, i.e. data drives or sections of a data drive, that are only for use as a store of source data node or redundant data. The systematic property may be maintained but a mapping introduced so that a data drive may store redundant data within a source data node and vice-versa. This interleaving of data changes the mapping of coded data to stored data and can be used to control the read operations from a data storage system, for example to ensure that the network traffic is balanced across the data storage system.

Although data storage is a particularly preferable application for the coding techniques disclosed herein embodiments include the generation of codes for any application, such as data transmission. For example, the nodes may correspond to data packets for transmission over a network.

The systematic coding techniques according to embodiments include erasure resilient systematic coding techniques.

The flow charts and descriptions thereof herein should not be understood to prescribe a fixed order of performing the method steps described therein. Rather, the method steps may be performed in any order that is practicable. Although the present invention has been described in connection with specific exemplary embodiments, it should be understood that various changes, substitutions, and alterations apparent to those skilled in the art can be made to the disclosed embodiments without departing from the spirit and scope of the invention as set forth in the appended claims.

Methods and processes described herein can be embodied as code (e.g., software code) and/or data. Such code and data can be stored on one or more computer-readable media, which may include any device or medium that can store code and/or data for use by a computer system. When a computer system reads and executes the code and/or data stored on a computer-readable medium, the computer system performs the methods and processes embodied as data structures and code stored within the computer-readable storage medium. In certain embodiments, one or more of the steps of the methods and processes described herein can be performed by a processor (e.g., a processor of a computer system or data storage system). It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), and magnetic and optical storage devices (hard drives, magnetic tape, CDs, DVDs); network devices; or other media now known or later developed that is capable of storing computer-readable information/data. Computer-readable media should not be construed or interpreted to include any propagating signals.

1-48. (canceled)

49. A method for determining how to encode data in accordance with a systematic coding technique and encoding data in accordance with the determined systematic coding technique, the method comprising:
determining the code parameters n, k, r and α, wherein n is the total number of nodes, k is the total number of source data nodes, r is the total number of redundant nodes, such that n=k+r, α is the number of substripes of data in one of the nodes and each of the source data nodes and redundant nodes comprise the same number of substripes, and wherein α is determined so that it satisfies either the condition 1<α<r^{m} or both of the conditions α=r^{m} and (k/r) is not an integer, where m=ceiling(k/r);
determining source data nodes that comprise source data that is not encoded by the systematic coding technique;
for each of the redundant nodes, determining to generate each of the substripes of data in dependence on a combination of a different substripe from each of the source data nodes such that each of the substripes is generated in dependence on a combination of k substripes of source data and the α substripes of the redundant node are generated in dependence on all of the (α×k) substripes of source data; and
determining each of one or more of the substripes of at least one of the redundant nodes to be further dependent on at least one further substripe of source data that it is not currently dependent on, wherein said determination comprises selecting a further substripe of source data for a redundant node to be further dependent on with the further substripe being selectable from any one of the k source nodes; and
encoding data in accordance with the determined systematic coding technique.

50. The method according to claim 49, wherein:
each of the substripes within each node is identifiable by substripe index level, i, where 1≤i≤α and i is an integer;
for at least one of the redundant nodes, said determining to generate each of the substripes of data in dependence on a combination of a different substripe from each of the source data nodes comprises determining, for each substripe of said at least one of the redundant nodes, the substripe of the redundant node to be a combination of a single substripe from all of the source data nodes with the substripe of the redundant node and the substripes from each source data nodes all having the same substripe index level;
in said step of determining each of one or more of the substripes of at least one of the redundant nodes to be further dependent on at least one further substripe of source data that it is not currently dependent on, the determination comprises selecting a further substripe of source data for a redundant node to be further dependent on with the further substripe being selectable from any one of the α substripe index levels; and, preferably, the determination comprises selecting substripes from the source data nodes as further substripes of source data that one or more of the redundant nodes are further dependent on with the selection comprising at least one substripe from each of the α substripe index levels;
wherein, for each substripe index level, there is at least one substripe of a redundant node that is dependent on an additional substripe of source data with a different substripe index level from the substripe of said at least one substripe of the redundant node;
wherein in said step of determining each of one or more of the substripes of at least one of the redundant nodes to be further dependent on at least one further substripe of source data that it is not currently dependent on, the determination comprises, for all but one of redundant nodes, the redundant nodes to be determined in dependence on at least one additional substripe of source data;
wherein in said step of determining each of one or more of the substripes of at least one of the redundant nodes to be further dependent on at least one further substripe of source data that it is not currently dependent on, the determination comprises selecting at least one substripe from each of the k source data nodes as further substripes of source data that one or more of the redundant nodes are further dependent on;
wherein in said step of determining each of one or more of the substripes of at least one of the redundant nodes to be further dependent on at least one further substripe of source data that it is not currently dependent on, the determination comprises selecting at least one substripe from each of the k source data nodes as further substripes of source data that one of the redundant nodes is further dependent on;
wherein in said step of determining each of one or more of the substripes of at least one of the redundant nodes to be further dependent on at least one further substripe of source data that it is not currently dependent on, the determination comprises, for each of two or more of the redundant nodes, selecting at least one substripe from each of the k source data nodes as further substripes of source data that the redundant node is further dependent on;
wherein (k/r) is not an integer;
wherein either r is 2 or more, or r is 3 or more;
wherein either α is 2 or more, or α is 3 or more;
wherein α is determined so that it satisfies the condition 1<α<r^{m} and/or (k/r) is not an integer;
wherein one of the redundant nodes is determined to have each of its substripes dependent on exactly k substripes of source data and the substripes of the redundant node are generated in dependence on all of the (α×k) substripes of source data;
wherein said determining of each of one or more of the substripes of at least one of the redundant nodes to be further dependent on at least one further substripe of source data that it is not currently dependent on is performed for r−1 redundant nodes;
wherein determining each of one or more of the substripes of a redundant node to be further dependent on at least one further substripe of source data that it is not currently dependent on is performed for all of the substripes of the node;
wherein the method further comprises performing a balanced selection of the substripes that the redundant nodes are further dependent on such that substantially the same number of read operations are required to recover each source node;
wherein the method is computer-implemented;
wherein the determined systematic coding technique is MDS;
wherein the combining of substripes of source data to generate a substripe of a redundant node is by linear combinations over finite fields; and
wherein the systematic coding technique is an erasure resilient systematic coding technique.

51. The method according to claim 49, wherein (k/r) is an integer.

52. The method according to claim 49, wherein said step of determining each of one or more of the substripes of at least one of the redundant nodes to be further dependent on at least one further substripe of source data that it is not currently dependent on is performed in accordance with any of a random determination, a pseudo-random determination, a pre-determined technique and/or an algorithm;
wherein, when determining each of one or more of the substripes of a redundant node to be further dependent on at least one further substripe of source data that it is not currently dependent on, the selection of each further substripe of source data is independent from the order of writing and reading the previous substripes of source data;
wherein:
said step of determining source data nodes comprises determining k source data nodes {d₁, d₂, . . . , dₖ} where each data node dⱼ comprises an indexed set of α substripes {a_{1,j}, a_{2,j}, . . . , a_{α,j}} as a two-dimensional array Data with a rows and k columns such that
$$Data = [ \begin{matrix}{a}_{1 , 1} & {a}_{1 , 2} & … & {a}_{1 , k} \\ {a}_{2 , 1} & {a}_{2 , 2} & … & {a}_{2 , k} \\ ⋮ & ⋮ & ⋱ & ⋮ \\ {a}_{α , 1} & {a}_{α , 2} & … & {a}_{α , k}\end{matrix} ] ;$$
and
the generation of the redundant nodes comprises:
determining r redundant data nodes {p₁, p₂, . . . , pᵣ} where each redundant node p₁, where 1≤l≤r, comprises of an indexed set of α substripes {p_{1,l}, p_{2,l}, . . . , p_{α,l}};
determining r two-dimensional index arrays P₁, . . . , Pᵣ;
determining the index array for P₁ to have α rows and k columns, where each cell in P₁ is a pair of indexes with the following values:
$${P}_{1} [ \begin{matrix}( 1 , 1 ) & ( 1 , 2 ) & … & ( 1 , k ) \\ ( 2 , 1 ) & ( 2 , 2 ) & … & ( 2 , k ) \\ ⋮ & ⋮ & ⋱ & ⋮ \\ ( α , 1 ) & ( α , 2 ) & … & ( α , k )\end{matrix} ] ;$$
determining the index arrays P₂, . . . , Pᵣ to have α rows and k+m columns, and where each cell in Pₗ, where 2≤l≤r, is a pair of indexes with the following values:
$${P}_{l} = [ \begin{matrix}( 1 , 1 ) & ( 1 , 2 ) & … & ( 1 , k ) & ( ? ,?) & … & ( ? ,?) \\ ( 2 , 1 ) & ( 2 , 2 ) & … & ( 2 , k ) & ( ? ,?) & … & ( ? ,?) \\ ⋮ & ⋮ & ⋱ & ⋯ & ⋮ & ⋱ & ( ? ,?) \\ ( α , 1 ) & ( α , 2 ) & … & ( α , k ) & ( ? ,?) & … & ( ? ,?)\end{matrix} ] ,$$
where the pairs with values (?,?) are further determined according to an algorithm; and
for each of the redundant nodes {p₁, p₂, . . . , pᵣ}, determining to generate each of the substripes p_{i,l} where 1≤i≤α and 1≤l≤r, in dependence on a combination of different source data substripes a₍ⱼ_{₁}_{,j}_{₂}₎, where the pair (j₁,j₂) is present in the i-th row of the index array Pₗ.

53. A method for determining how to generate a systematic code and encoding data in accordance with the determined systematic code, the method comprising:
receiving the code parameters n, α, k and/or r;
configuring an algorithm with the received code parameters;
determining, by the algorithm, how to generate a systematic code according to the method of claim 49; and
encoding data in accordance with the determined systematic code;
wherein n, k, α are inputs to the algorithm and index arrays P₁, . . . , Pᵣ are outputs that define how to generate each of the redundant nodes, and wherein the algorithm performs the steps of:
initialising P₁, . . . , Pᵣ as arrays P=((i,j))_{α×k};
appending additional m=┌k/r┐ columns to P₂, . . . , Pᵣ all initialized to (0,0);
$$setting portion ← ⌈ \frac{α}{r} ⌉ ;$$
setting ValidPartitions←∅;
setting j←0;
repeating the steps of:
$$setting j ← j + 1 ;$$
$$setting v ← ⌈ \frac{j}{r} ⌉ ;$$
$$setting run ← ⌈ \frac{α}{{r}^{v}} ⌉ ;$$
$$setting step ← ⌈ \frac{α}{r} ⌉ - run ;$$
determining
Dⱼ_{ⱼ}=ValidPartitioning(ValidPartitions,k,r,portion,run,step,Jᵥ);
setting ValidPartitions=ValidPartitions ∪D_{d}_{ⱼ}; and
determining one D_{ρ,d}_{ⱼ}∈Dⱼ, such that its elements correspond to row indexes in the (k+v)-th column in one of the arrays P₂, . . . , Pᵣ, that are all zero pairs (0,0), wherein the indexes in D_{ρ,d}_{ⱼ} are the row positions where the pairs (i,j) with indexes i∈D\D_{ρd}_{ⱼ} are assigned in the (k+v)-th column of P₂, . . . , Pᵣ;
until (run>1) AND (j≠0 mod r);
while j<k, performing the steps of:
setting j←j+1;
setting v←┌j/r┐;
setting run←0;
determining
D_{d}_{ⱼ}=ValidPartitioning(ValidPartitions,k,r,portion,run,step,Jᵥ);
setting ValidPartitions=ValidPartitions ∪D_{d}_{ⱼ};
determining one D_{ρ,d}_{ⱼ}∈D_{d}_{ⱼ} such that its elements correspond to row indexes in the (k+v)-th column in one of the arrays P₂, . . . , Pᵣ that are all zero pairs (0, 0), wherein the indexes in D_{ρ,d}_{ⱼ} are the row positions where the elements (i,j) with indexes i∈D\D_{ρ,d}_{ⱼ} are assigned in the (k+v)-th column of P₂, . . . , Pᵣ; and
when the condition j<k is no longer satisfied, outputting the determined P₁, . . . , Pᵣ;
wherein, the steps of the algorithm further comprise:
partitioning the set Nodes={d₁, . . . , dₖ} of k data disks in ┌k/r┐ disjunctive subsets
$${J}_{1} , … , {J}_{⌈ \frac{k}{r} ⌉}$$
where |Jᵥ|=r and where if r does not divide k then the last subset
$${J}_{⌈ \frac{j}{r} ⌉}$$
has k mod r elements and where
$$Nodes = {⋃}_{v = 1}^{⌈ \frac{k}{r} ⌉} {J}_{v} . ;$$
wherein the function ValidPartitioning is called by the algorithm and takes ValidPartitions,k,r,portion,run,step,Jᵥ as inputs and outputs D_{d}_{ⱼ}={D_{1,d}_{ⱼ}, . . . , D_{r,d}_{ⱼ}}; and
the ValidPartitioning function comprises the steps of:
setting D={1, 2, . . . , α};
if run≠0 then
finding D_{d}_{ⱼ} that satisfies Condition 1 and Condition 2;
else
finding D_{d}_{ⱼ} that satisfies Condition 2;
where Condition 1 is that at least one subset D_{ρ,d}_{ⱼ} has portion elements with runs of run consecutive elements separated with a distance between the indexes equal to step, wherein the elements of that subset correspond to row indexes in the (k+v)-th column in one of the arrays P₂, . . . , Pᵣ, that are all zero pairs (0, 0), and the distance between two elements in one node is computed in a cyclical manner such that the distance between the elements a_{α-1} and a₂ is 2; and
Condition 2 is that a necessary condition for the valid partitioning of the elements in the systematic nodes to achieve the lowest possible repair bandwidth is
$${D}_{{d}_{{j}_{1}}} = {D}_{{d}_{{j}_{2}}}$$
for all dⱼ_{₁} and dⱼ_{₂} in Jᵥ and
$${D}_{{d}_{{j}_{1}}} \neq {D}_{{d}_{{j}_{2}}}$$
for all dⱼ_{₁} and dⱼ_{₂} systematic nodes in the system, and if portion divides α, then D_{ρ,d}_{ⱼ} for all dⱼ in the Jᵥ-th subset are disjunctive, i.e., D=∪ⱼ₌₁^{r} D_{ρ,d}_{ⱼ}={1, 2, . . . , α};
wherein the combining of substripes of source data to generate a substripe p_{i,l} of the redundant node pₗ is by linear combinations over finite fields according to the index arrays P₁, . . . , Pᵣ; and
wherein p_{i,l}=Σc_{l,j}_{₁}_{,j}_{₂}, where 1≤i≤α, 1≤l≤r and the pair (j₁,j₂) exists in the i-th row of the index array Pₗ and co-efficient c_{l,j}_{₁}_{,j}_{₂} is a non-zero element in the finite field.

54. A method for storing data in a data storage system, wherein n is the total number of data storage nodes of the data storage system, k is the total number of source data nodes of the data storage system, r is the total number of redundant data nodes of the data storage system, such that n=k+r, α is the number of substripes of data in one of the nodes and each of the source data nodes and redundant data nodes comprise the same number of substripes, and wherein α satisfies either the condition 1<α<r^{m} or both of the conditions α=r^{m} and (k/r) is not an integer, where m=ceiling(k/r), the method comprising:
determining how to encode the source data for storing in the data storage system in dependence on the systematic coding technique according to claim 49;
determining the redundant data by encoding the source data in accordance with the determined systematic coding technique; and
storing the source data and the redundant data in the data storage nodes of the data storage system.

55. The method according to claim 54, further comprising performing a mapping operation on the source data and encoded source data such that one or more of the data storage nodes stores both source data and encoded source data.

56. A method of coding source data, the method comprising:
obtaining source data; and
encoding the source data in accordance with a systematic coding technique determined according to claim 49;
the method further comprising transferring the source data and redundant data over a network.

57. A computing system configured to perform the method according to claim 49.

58. A computer program that, when executed by a computing system, causes the computing system to perform the method according to claim 49.

59. A data storage system, wherein n is the total number of data storage nodes of the data storage system, k is the total number of source data nodes of the data storage system, r is the total number of redundant data nodes of the data storage system, such that n=k+r, α is the number of substripes of data in one of the nodes and each of the source data nodes and redundant data nodes comprise the same number of substripes, and wherein α satisfies either the condition 1<α<r^{m} or both of the conditions α=r^{m} and (k/r) is not an integer, where m=ceiling(k/r), the data storage system configured to store data in accordance with the method of claim 54.

60. A method of recovering a node that is one of a plurality of systematically coded source and redundant nodes, the method comprising applying a decoding method that is the inverse of the method according to claim 49.

61. A method of recovering one of a plurality of nodes, wherein the plurality of nodes have been coded according to the method of claim 49, the method comprising:
obtaining a set of
$$⌈ \frac{α}{r} ⌉$$
substripes of data from nodes of the plurality of nodes other than the node being recovered;
obtaining one or more further substripes of data from nodes of the plurality of nodes other than the node being recovered;
using the obtained set of
$$⌈ \frac{α}{r} ⌉$$
stripes to recover one or more substripes of the node being recovered; and
recovering all of the other substripes of the node being recovered in dependence on the one or more further substripes and a re-use of the obtained set of
$$⌈ \frac{α}{r} ⌉$$
substripes.

62. A method for recovering one of a plurality of nodes that have been coded according to the method of claim 49, the method comprising:
receiving data defining how the plurality of nodes were coded;
configuring an algorithm with the received data; and
determining, by the algorithm, how to recover the node in dependence on data in the other of the plurality of nodes;
wherein the algorithm recovers a node, dₗ, by performing the following steps:
accessing and transferring
$$( k - 1 ) ⌈ \frac{α}{r} ⌉$$
elements a_{i,j} from all k−1 non-failed systematic nodes and
$$⌈ \frac{α}{r} ⌉$$
elements p_{i,1} from p₁ where i∈D_{ρ,d}_{ₗ};
repairing a_{i,l}∈D_{ρ,d}_{ₗ};
accessing and transferring
$$( r - 1 ) ⌈ \frac{α}{r} ⌉$$
elements p_{i,j} from p₂, . . . , pᵣ where i∈D_{ρ,d}_{ⱼ};
accessing and transferring from the systematic nodes the elements a_{i,j} indexed in the i-th row of the index arrays P₂, . . . , Pᵣ where i∈D_{ρ,d}_{ⱼ} that are different from said accessed and transferred
$$( k - 1 ) ⌈ \frac{α}{r} ⌉$$
elements a_{i,j} from all k−1 non-failed systematic nodes and
$$⌈ \frac{α}{r} ⌉$$
elements p_{i,1} from p₁; and
repairing a_{i,l} where i∈D\D_{ρ,d}_{ₗ}; and
wherein:
p₁, . . . , pᵣ are redundant data nodes with respective index arrays P₁, . . . , Pᵣ.

63. The method according to claim 62, wherein the nodes are nodes of a data storage system.

64. A method of reading data from a data storage system, the method comprising reading data in dependence on the method according to claim 62.

65. A method of recovering up to r failed nodes from a plurality of systematically coded source and redundant nodes, the method being equivalent to decoding data in dependence on the inverse of the generator matrix for implementing the coding technique according to claim 49.

66. The method according to claim 60, wherein the method is computer-implemented.

67. A computing system configured to perform the method according to claim 62.

68. A computer program that, when executed by a computing system, causes the computing system to perform the method according to claim 62.
